(19) United States
(12) Patent Application Publication
(10) Pub. No.: US 2021/0296368 A1
(43) Pub. Date: Sep. 23, 2021

(54) DISPLAY SUBSTRATE AND MANUFACTURING METHOD THEREFOR, AND DISPLAY PANEL AND DISPLAY APPARATUS

(71) Applicants: Hefei Xinsheng Optoelectronics Technology Co., Ltd., Hefei (CN); BOE Technology Group Co., Ltd., Beijing (CN)

(72) Inventors: Wei SONG, Beijing (CN); Ce ZHAO, Beijing (CN); Yuankui DING, Beijing (CN); Ming WANG, Beijing (CN); Ning LIU, Beijing (CN); Yingbin HU, Beijing (CN); Junlin PENG, Beijing (CN); Liusong NI, Beijing (CN)

(21) Appl. No.: 17/264,827

(22) PCT Filed: Jun. 15, 2020
(86) PCT No.: PCT/CN2020/096162

§ 371 Date: Jan. 31, 2021

(30) Foreign Application Priority Data
Jun. 19, 2019 (CN) 201910531872.3

(51) Int. Cl. H01L 27/12

(52) U.S. Cl. CPC H01L 27/1244; H01L 27/1288

(57) ABSTRACT

Provided are a display substrate and a manufacturing method therefor, and a display panel and a display apparatus. The gate insulation layer included in the display substrate comprises a first branch portion located between the gate electrode and the active layer, and a second branch portion located below an overlapping region of the first routing and the second routing; a part, extending out of the gate electrode, of the first branch portion has a first width value; at the overlapping region between the second routing and the first routing, a part, extending out of the first routing, of the second branch portion has a second width value; and the first width value is greater than the second width value.

### CROSS REFERENCE TO RELATED APPLICATIONS

The present disclosure claims priority to Chinese Patent Application No. 201910531872.3 filed with the China National Intellectual Property Administration on Jun. 19, 2019, and entitled ‘DISPLAY SUBSTRATE AND MANUFACTURING METHOD THEREFOR, AND DISPLAY PANEL’, the entire contents of which are incorporated herein by reference.

### FIELD

The present disclosure relates to the field of display technology, in particular to a display substrate and a manufacturing method therefor, and a display panel and a display apparatus.

### BACKGROUND

Thin film transistors (TFTs) are mainly used for driving sub-pixels of liquid crystal display (LCD) and organic light-emitting diode (OLED) and other displays. A drive backplane made of an TFT array is a key component for a display screen to achieve higher pixel density and aperture ratio and improve brightness.

### SUMMARY

An embodiment of the present disclosure provides an array substrate, including:

a base substrate;

an active layer located on the base substrate;

a gate metal layer located on the active layer, wherein the gate metal layer includes a gate and a first lead, an orthographic projection of the gate on the base substrate and an orthographic projection of the active layer on the base substrate have an overlapping region with each other, and an orthographic projection the first lead on the base substrate and the orthographic projection of the active layer on the base substrate do not overlap each other;

a source-drain metal layer located on the gate metal layer, wherein the source-drain metal layer includes a source, a drain and a second lead, the source and the drain are electrically connected to the active layer, and an orthographic projection of the second lead on the base substrate and the orthographic projection of the first lead on the base substrate have an overlapping region with each other; and

a gate insulation layer located between the active layer and the gate metal layer, wherein the gate insulation layer includes a first portion and a second portion, wherein an orthographic projection of the first portion on the base substrate covers and exceeds the orthographic projection of the gate on the base substrate, and an orthographic projection of the second portion on the base substrate covers the orthographic projection of the first lead on the base substrate;

wherein a part, extending out of the gate, of the first portion has a first width value; at the overlapping region formed by the second lead and the first lead, a part, extending out of the first lead, of the second portion has a second width value; and the first width value is greater than the second width value.

Optionally, in the above-mentioned display substrate provided in the embodiment of the present disclosure, the second width value is less than or equal to 20% of the first width value.

Optionally, in the above-mentioned display substrate provided in the embodiment of the present disclosure, the second width value is 0.

Optionally, in the above-mentioned display substrate provided in the embodiment of the present disclosure, an extension direction of the second lead and an extension direction of the first lead are different; and the orthographic projection of the first lead on the base substrate and the orthographic projection of the second portion on the base substrate overlap each other.

Optionally, the above-mentioned display substrate provided in the embodiment of the present disclosure further includes an interlayer insulation layer located between the gate metal layer and the source-drain metal layer; and the source and the drain are electrically connected to the active layer through via holes running through the interlayer insulation layer.

In another aspect, an embodiment of the present disclosure further provides a manufacturing method for the above-mentioned display substrate, including:

forming a pattern of an active layer on a base substrate;

forming an insulation film and a gate metal film successively on the pattern of the active layer;

forming a patterned photoresist layer on the gate metal film by using a semi-exposure photolithography process;

etching the gate metal film by using the patterned photoresist layer as a shield to form a pattern of a gate metal layer including a gate and a first lead;

dry etching the insulation film by using the patterned photoresist layer as a shield to form a pattern of a gate insulation layer including a first portion and a second portion, and removing the photoresist layer; and

forming a pattern of a source-drain metal layer including a source, a drain and a second lead on the pattern of the gate insulation layer.

Optionally, in the above-mentioned method provided in the embodiment of the present disclosure, the forming the patterned photoresist layer on the gate metal film by using the semi-exposure photolithography process includes:

forming a positive photoresist film on the gate metal film; and

performing exposure and development treatment on the positive photoresist film by using a halftone mask or a gray tone mask, wherein in the pattern of the photoresist layer obtained, a part above a gate to be formed has a first thickness, and a part in an overlapping region formed by a first lead and a second lead to be formed has a second thickness, the first thickness being greater than the second thickness.

Optionally, in the above-mentioned method provided in the embodiment of the present disclosure, the half-tone mask or the gray-tone mask includes a completely light-transmitting area and a partially light-transmitting area, the completely light-transmitting area corresponds to the first thickness in the photoresist layer, and the partially light-transmitting area corresponds to the second thickness in the photoresist layer.

Optionally, in the above-mentioned method provided in the embodiment of the present disclosure, the second thickness is less than or equal to half of the first thickness.

Optionally, in the above-mentioned method provided in the embodiment of the present disclosure, before the forming the pattern of the source-drain metal layer including the source, the drain and the second lead on the pattern of the gate insulation layer, the method further includes: forming an interlayer insulation layer with via holes on the pattern of the gate insulation layer, so that the source and the drain to be formed are electrically connected to the active layer through the via holes.

In yet another aspect, an embodiment of the present disclosure further provides a display panel including the above-mentioned display substrate provided in an embodiment of the present disclosure.

In still another aspect, an embodiment of the present disclosure further provides a display apparatus including the above-mentioned display panel provided in an embodiment of the present disclosure.

### BRIEF DESCRIPTION OF THE DRAWINGS

FIG. 1 is a schematic sectional diagram of a display substrate provided in the related art.

FIG. 2 is a schematic sectional diagram of a display substrate provided in the related art.

FIG. 3 is a schematic sectional diagram of a display substrate provided in an embodiment of the present disclosure.

FIG. 4 is a flow diagram of a manufacturing method for a display substrate provided in an embodiment of the present disclosure.

FIG. 5 is a schematic structural diagram in a process of manufacturing a display substrate provided in an embodiment of the present disclosure.

FIG. 6 is a schematic structural diagram in a process of manufacturing a display substrate provided in an embodiment of the present disclosure.

FIG. 7 is a schematic structural diagram in a process of manufacturing a display substrate provided in an embodiment of the present disclosure.

FIG. 8 is a schematic structural diagram in a process of manufacturing a display substrate provided in an embodiment of the present disclosure.

FIG. 9 is a schematic structural diagram in a process of manufacturing a display substrate provided in an embodiment of the present disclosure.

FIG. 10 is a schematic structural diagram in a process of manufacturing a display substrate provided in an embodiment of the present disclosure.

FIG. 11 is a schematic structural diagram in a process of manufacturing a display substrate provided in an embodiment of the present disclosure.

### DETAILED DESCRIPTION OF THE EMBODIMENTS

To make the objects, technical solutions and advantages of the present disclosure clearer, technical solutions in the embodiments of the present disclosure will be described clearly and completely with reference to the drawings in the embodiments of the present disclosure. It should be understood that preferred embodiments described below are only used for illustrating and explaining the present invention, and are not intended to limit the present invention. Moreover, the embodiments in the present disclosure and the features in the embodiments can be combined with each other without conflict.

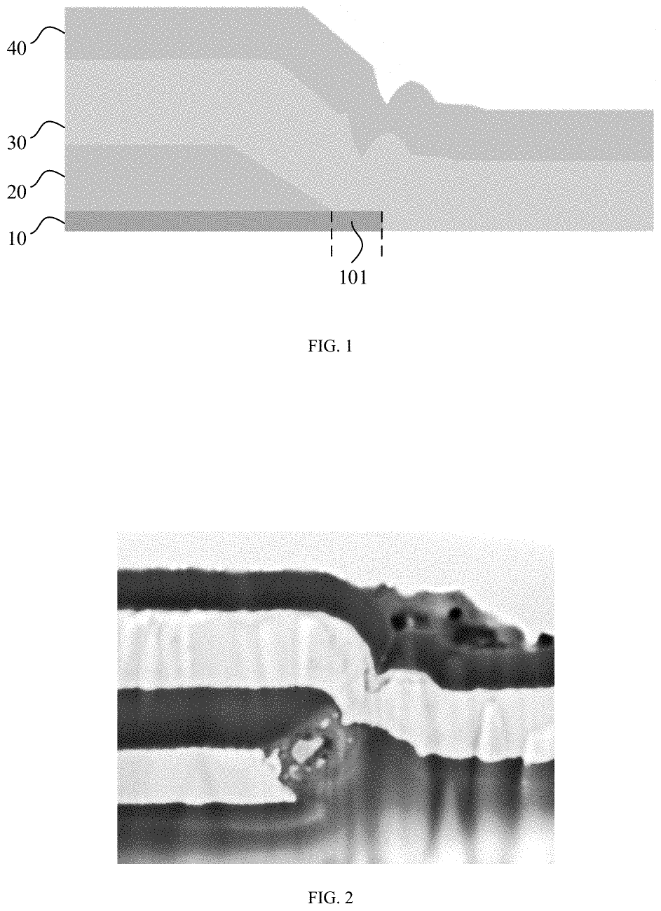

Generally, a TFT of a top emission structure can effectively reduce the parasitic capacitance, and achieves a high refresh frequency; and it has a shorter channel and a smaller size, which can better meet the needs of the development of display panels. However, the performance of the TFT of the top-emission structure is liable to be influenced by a short channel effect. To reduce the influence of the short channel effect on the TFT of the top-emission structure, it should be ensured that during preparation of the TFT of the top-emission structure, the length of a gate insulation layer (Gate Insulator, GI) 10 is greater than the length of a gate metal layer (Gate) 20, as shown in FIG. 1. An extra part of GI 10 with respect to the gate 20 is called a gate insulation layer tail (GI tail) 101.

In areas where the TFT is not located, such as in a metal routing area, the GI tail causes wrinkles at a contact area between an interlayer insulation layer (inter layer dielectrics, ILD) 30 and the gate 20. After lap-joint of a source-drain metal layer (SD) 40, such wrinkles cause the ILD 30 between the gate 20 and the SD 40 to have worse coverage and a smaller thickness, which leads to a phenomenon like a tip point after the SD 40 is deposited, as shown in FIG. 2, such that a short-circuit (data gate short, DGS) failure between the gate metal layer and the source-drain metal layer is prone to occur.

In view of this, in a display substrate provided in embodiments of the present disclosure, the proportion of the gate insulation layer at the metal routing overlapping region is reduced to be smaller than a value of the GI tail. That is, the GI tail is removed as much as possible in the metal routing overlapping region, to reduce DGS failures and improve the yield of the display substrate.

Specific implementations of the display substrate, a manufacturing method therefor, and a display panel and a display apparatus provided in embodiments of the present disclosure will be described in detail below in conjunction with the accompanying drawings. The thickness and shape of each film layer in the drawings do not reflect the true scale, and are merely intended to illustrate the present disclosure.

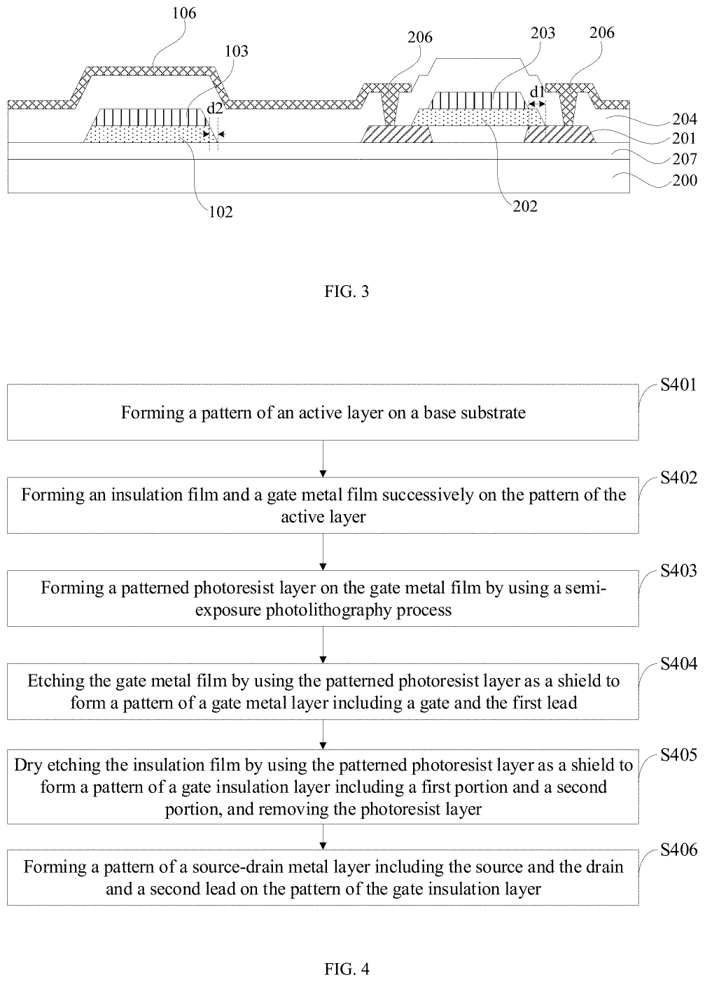

Referring to FIG. 3, an embodiment of the present disclosure provides a display substrate, including:

a base substrate 200;

an active layer 201 located on the base substrate 200;

a gate metal layer located on the active layer 201, wherein the gate metal layer includes a gate 203 and a first lead 103, wherein an orthographic projection of the gate 203 on the base substrate 200 and an orthographic projection of the active layer 201 on the base substrate 200 have an overlapping region with each other, and an orthographic projection the first lead 103 on the base substrate 200 and the orthographic projection of the active layer 201 on the base substrate 200 do not overlap each other;

a source-drain metal layer located on the gate metal layer, wherein the source-drain metal layer includes a source and a drain 206 and a second lead 106, wherein the source and the drain 206 are electrically connected to the active layer 201, and an orthographic projection of the second lead 106 on the base substrate 200 and the orthographic projection of the first lead 103 on the base substrate 200 have an overlapping region with each other; and

a gate insulation layer located between the active layer 201 and the gate metal layer, wherein the gate insulation layer includes a first portion 202 and a second portion 102, an orthographic projection of the first portion 202 on the base substrate 200 covers and exceeds the orthographic projection of the gate 203 on the base substrate 200, and an orthographic projection of the second portion 102 on the base substrate 200 covers the orthographic projection of the first lead 103 on the base substrate 200;

wherein a part, extending out of the gate 203, of the first portion 202 has a first width value d1; at the overlapping region formed by the second lead 106 and the first lead 103, a part, extending out of the first lead 103, of the second portion 102 has a second width value d2; and the first width value d1 is greater than the second width value d2.

Specifically, in the above-mentioned display substrate provided in the embodiment of the present disclosure, a region where the active layer 201, the gate 203, and the source and the drain 206 are located may be called a control region or transistor region, and a region where the first lead 103 and the second lead 106 overlap is called a metal routing region, and the control region and the metal routing region are independent from each other.

Specifically, the area of the first portion 202 of the gate insulation layer in the control region is larger than the area of the gate 203 thereon. It may also be deemed as that along a channel extension direction of the active layer 201, the length of the first portion 202 of the gate insulation layer is greater than the length of the gate 203. That is, it may be understood as that there is a GI tail in the control region. In conductive treatment on the active layer 201, a region covered by the GI tail is not subjected to the conductor treatment, and therefore, when manufacturing the display substrate, a channel length of the active layer 201 can be regulated and controlled by controlling the first width value d1 of the part, extending out of the gate 203, of the first portion 202, so as to minimize the influence of the short channel effect.

Specifically, in the above-mentioned display substrate provided in the embodiment of the present disclosure, the first lead 103 may be a signal line such as a gate line, and the second lead 106 may be a signal line such as a data line and a touch line. An extension direction of the first lead 103 and an extension direction of the second lead 106 are generally different. For example, a gate line as the first lead 103 generally extends along a row direction of the display substrate, and a data line as the second lead 106 generally extends along a column direction of the display substrate, and the data line and the gate line are insulated from each other at an overlapping position. Of course, it is not excluded that the first lead and the second lead existing as adapter lines or jumper lines extend in the same direction at a specific position, and are electrically connected to each other in the overlapping region. Since the first lead 103 and the second lead 106 are only used for transmitting signals, the active layer with a channel region is generally not provided under them, and thus the GI tail does not need to exist under the first lead 103. Based on this, in the above-mentioned display substrate provided in the embodiment of the present disclosure, the size of the second portion 102 located below the first lead 103 and the second lead 106 in the overlapping region is minimized, so as to minimize an edge difference, i.e. the second width value d2 between the second portion 102 and the first lead 103 in the overlapping region, to reduce the GI tail in the overlapping region and alleviate wrinkles in the overlapping region, thereby reducing DGS failures, and improving the yield of the display substrate.

During specific implementation, the second width value d2 may be 0, which means that in the overlapping region, the second portion 102 does not exceed a region where the first lead 103 is located, and their sizes are same to completely avoid DGS failures caused by the GI tail.

Moreover, to reduce the difficulty of the manufacturing process, except for the overlapping region, the GI tail can be completely removed from all the second portion 102 under the first lead 103, that is, the orthographic projection of the first lead 103 on the base substrate 200 and the orthographic projection of the second portion 102 on the base substrate 200 coincide with each other.

In another possible implementation, the second width value d2 is less than or equal to 20% of the first width value d1, that is, the size of the second portion 102 in the overlapping region is greater than the size of the first lead 103, and their size difference is smaller than the size of the GI tail, so as to minimize the size of the GI tail in the overlapping region, which reduces the requirement for the process and is easier to implement.

Further referring to FIG. 3, the above-mentioned display substrate provided in the embodiment of the present disclosure generally further includes an interlayer insulation layer 204 located between the gate metal layer and the source-drain metal layer, i.e. the interlayer insulation layer 204 is further provided between the gate 203 and the source-drain metal layer 205, the interlayer insulation layer 204 being provided across the entire span, and the source and the drain 206 are electrically connected to the active layer 201 through via holes running through the interlayer insulation layer 204. A portion of the interlayer insulation layer 204 between the first lead 103 and the second lead 106 can function to insulate them from each other. Reducing the size of or eliminate the GI tail in the overlapping region can alleviate or eliminate wrinkles of the interlayer insulation layer 204 at the overlapping region, and can avoid DGS failures due to a phenomenon like point discharge of such wrinkles after the formation of the second lead 106.

Still referring to FIG. 3, the above-mentioned display substrate provided in the embodiment of the present disclosure generally may further include a buffer layer (buffer) 207 located between the base substrate 200 and the active layer 201, and other layers located above the source-drain metal layer, which will not be described in detail here.

Based on the same inventive concept, an embodiment of the present disclosure further provides a display panel including any display substrate as described above. The display panel may be any display panel including a display substrate, such as a liquid crystal display panel, an organic electroluminescent display panel, a plasma display panel, or the like. The display panel may be a rigid display panel, and may also be a flexible display panel. For the implementation of the display panel, reference may be made to the embodiment of the above-mentioned display panel, and repeated description is omitted. In the case where the display panel is a liquid crystal display panel, it may also include a pixel electrode layer, an insulation layer, and a common electrode layer above the source-drain metal layer, and may also be provided with a color filter substrate opposite to the display substrate, and a liquid crystal layer located between the color filter substrate and the display substrate, etc. In the case where the display panel is an organic electroluminescent display panel, it may also include a planarization layer, an anode layer, a pixel defining layer, an organic light-emitting function film layer, a cathode layer and other film layers, as well as a packaging structure, above the source-drain metal layer.

Based on the same inventive concept, an embodiment of the present invention further provides a display apparatus including the above-mentioned display panel provided in an embodiment of the present invention. The display apparatus may be a mobile phone, a tablet computer, a television, a display, a notebook computer, a digital photo frame, a navigator, or any other product or component with a display function. Other indispensable components of the display apparatus are present as understood by those of ordinary skill in the art, and are not described here, nor should they be construed as limiting the present invention. For the implementation of the display apparatus, reference may be made to the embodiment of the display panel described above, and repeated description is omitted.

Referring to FIG. 4, based on the same inventive concept, an embodiment of the present disclosure further provides a manufacturing method for a display substrate described above, the manufacturing method including the following steps.

S401, forming a pattern of an active layer 201 on a base substrate 200.

S402, forming an insulation film 302 and a gate metal film 303 successively on the pattern of the active layer 201.

S403, forming a patterned photoresist layer 205 on the gate metal film 303 by using a semi-exposure photolithography process.

S404, etching the gate metal film 303 by using the patterned photoresist layer 205 as a shield to form a pattern of a gate metal layer including a gate 203 and the first lead 103.

S405, dry etching the insulation film 302 by using the patterned photoresist layer 205 as a shield to form a pattern of a gate insulation layer including a first portion 202 and a second portion 102, and removing the photoresist layer 205.

S406, forming a pattern of a source-drain metal layer including the source, the drain 206 and a second lead 106 on the pattern of the gate insulation layer.

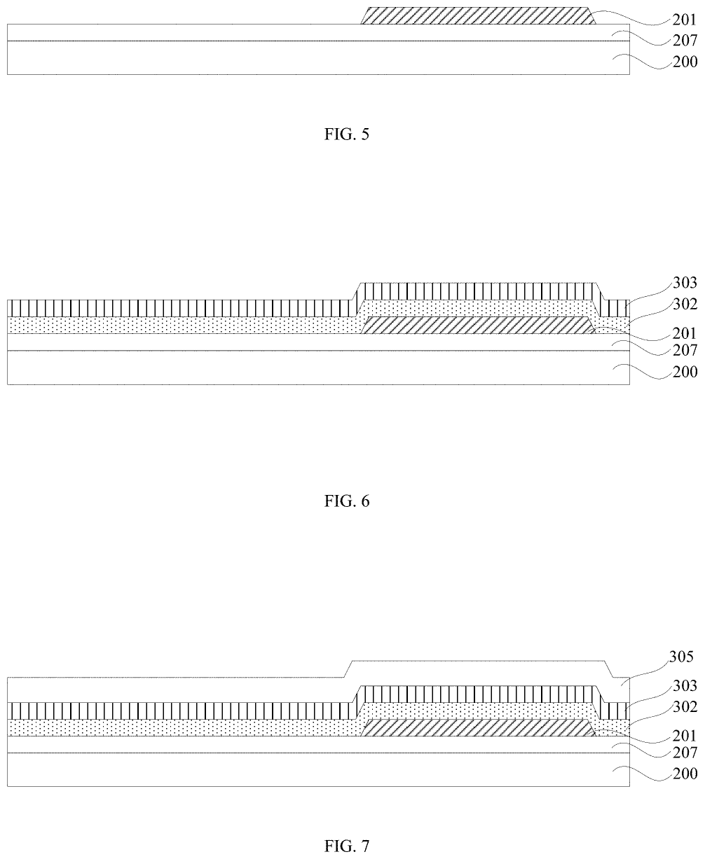

In specific implementation, referring to FIG. 5, forming the pattern of the active layer 201 on the base substrate 200 in the above step S401 may be specifically: firstly depositing a layer of insulation film on the base substrate 200 by using a plasma enhanced chemical vapor deposition (PECVD) process, such as depositing a layer of silicon oxide, silicon nitride or the like as a buffer layer (Buffer) 207; then depositing an oxide semiconductor film on the buffer layer 207, such as depositing indium gallium zinc oxide (IGZO), indium zinc oxide (IZO) or the like as the active layer 201 (Active); subsequently, patterning the active layer 201 using a mask by an etching process to form the pattern of the active layer 201. Alternatively, the pattern of the active layer 201 may also be prepared by using a material such as polysilicon, which is not limited here.

In specific implementation, referring to FIG. 6, forming the insulation film 302 and the gate metal film 303 successively on the pattern of the active layer 201 in the above step S402 may be specifically: depositing a layer of insulation film 302, such as depositing a layer of silicon oxide, silicon nitride or the like, on the active layer 201 by PECVD, and then depositing a layer of gate metal film 303, such as depositing copper (Cu), aluminum (Al) or the like, on the insulation film 302 by using a magnetron sputtering device.

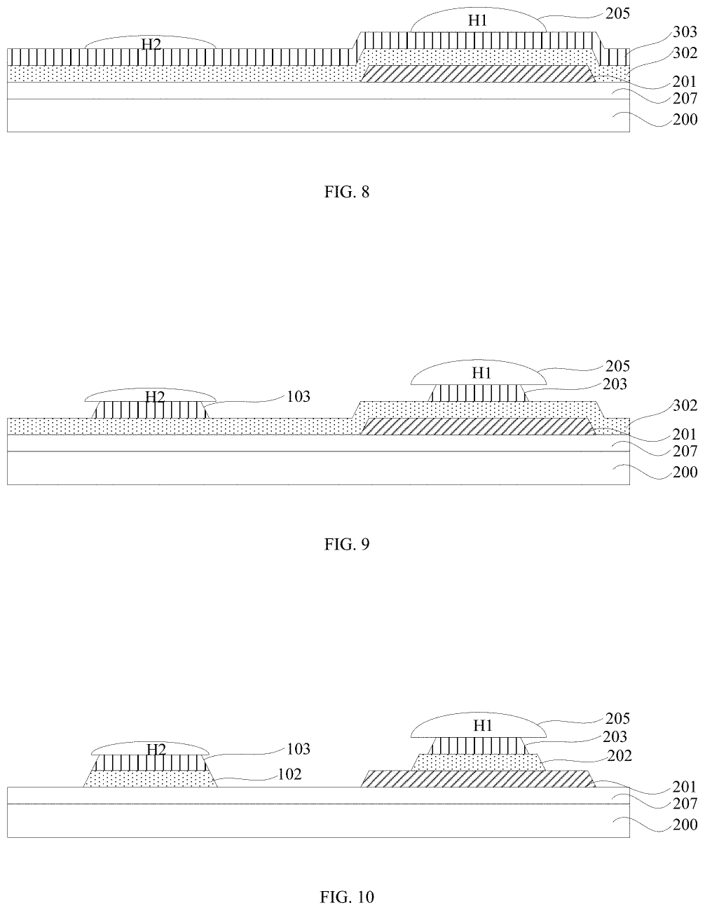

In specific implementation, referring to FIGS. 7 and 8, forming the patterned photoresist layer 205 on the gate metal film 303 by using a half-tone mask in above step S403 may specifically include the following steps.

Referring to FIG. 7, firstly, a positive photoresist film 305 is formed on the gate metal film 303.

Referring to FIG. 8, subsequently, exposure and development treatment is performed on the positive photoresist film 305 by using a half-tone mask or a gray-tone mask, wherein in the pattern of the obtained photoresist layer 205, a part above a gate 203 to be formed has a first thickness H1, a part in an overlapping region between a first lead 103 and a second lead 106 to be formed has a second thickness H2, and the first thickness H1 is greater than the second thickness H2.

Specifically, the half-tone mask or the gray-tone mask includes a completely light-transmitting area and a partially light-transmitting area, the completely light-transmitting area corresponds to the first thickness H1 in the photoresist layer 205, and the partially light-transmitting area corresponds to the second thickness H2 in the photoresist layer 205, and the completely light-transmitting area and the partially light-transmitting area have different UV-transmitting abilities. After exposure and development treatment is performed on the positive photoresist film by using the half-tone mask, the unexposed photoresist film can be removed, and the thickness at the position corresponding to the partially light-transmitting area is smaller than the thickness at the position corresponding to the completely light-transmitting area.

Moreover, the second thickness H2 obtained after the final exposure and development can be controlled to be less than or equal to half of the first thickness H1 by adjusting the exposure time and the exposure amount, so that there is a GI tail under the gate 103, and the GI tail in the overlapping region is removed.

In specific implementation, referring to FIG. 9, the above step S404 may be specifically performing an etching process on the gate metal film 303 by using the patterned photoresist layer 205 as a shield to form a pattern of a gate metal layer including a gate 203 and the first lead 103.

In specific implementation, referring to FIG. 10, when the insulation film 302 is dry etched by using the patterned photoresist layer 205 as a shield in the above step S405, since the second thickness H2 is smaller than the first thickness H1, edge portions of the smaller second thickness H2 are ashed faster during dry etching, such that the gradual size decrease of the photoresist layer 205 of the second thickness H2 is faster than the gradual size decrease of the photoresist layer 205 of the first thickness H1. The photoresist layer 205 of the second thickness H2 can be controlled to have almost the same size as the first lead 103 below. As the size of the photoresist layer 205 of the second thickness H2 becomes smaller, the region covered in the insulation film 302 also becomes smaller, and the size of the first portion 102 in the pattern of the gate insulation layer is substantially same as that of the first lead 103, so that the influence of the GI tail can be eliminated. Furthermore, since the photoresist layer 205 of the first thickness H1 is relatively thicker, edge portions thereof are ashed slower during dry etching, such that the size of the photoresist layer 205 of the first thickness H1 is substantially unchanged, which can ensure the existence of the GI tail on the active layer 201.

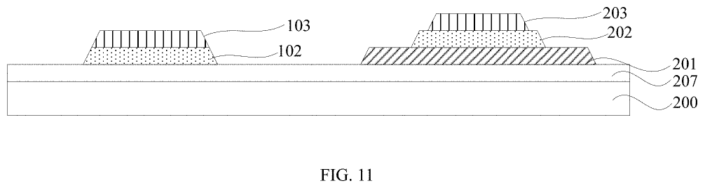

Subsequently, the remaining photoresist layer 205 can be removed by using a stripping solution to obtain a structure shown in FIG. 11.

In some embodiments, after the formation of the pattern of the gate insulation layer, that is, before forming a pattern of a source-drain metal layer including a source and a drain and a second lead on the pattern of the gate insulation layer in the above step S406, the method further includes: if the active layer is prepared from a polysilicon material, performing conductor treatment on the active layer 201 by using the gate metal layer and the gate insulation layer as a shield; and forming an interlayer insulation layer with via holes on the pattern of the gate insulation layer 204, so that the source and the drain 206 are electrically connected to the active layer 201 through the via holes.

In summary, in the display substrate in the embodiment of the present disclosure, the GI tail under the active layer is retained, and the size of the GI tail in the overlapping region of the first lead and the second lead is reduced. It can be understood that the GI tail should be removed as much as possible in the overlapping region of the first lead and the second lead, so that the size of the second portion of the gate insulation layer is same as or similar to the size of the first lead, thereby reducing DGS failures due to wrinkles in the overlapping region, and improving the yield of the display substrate.

It will be apparent to those skilled in the art that various modifications and variations can be made in the present disclosure without departing from the spirit or scope of the present disclosure. Thus, it is intended that the present disclosure covers the modifications and variations if these modifications and variations of the present disclosure come within the claims of the present disclosure and the scope of their equivalents.

1. A display substrate, comprising:
a base substrate;
an active layer located on the base substrate;
a gate metal layer located on the active layer, wherein the gate metal layer comprises a gate and a first lead, wherein an orthographic projection of the gate on the base substrate and an orthographic projection of the active layer on the base substrate have an overlapping region with each other, and an orthographic projection the first lead on the base substrate and the orthographic projection of the active layer on the base substrate do not overlap each other;
a source-drain metal layer located on the gate metal layer, wherein the source-drain metal layer comprises a source, a drain and a second lead, the source and the drain are electrically connected to the active layer, and an orthographic projection of the second lead on the base substrate and the orthographic projection of the first lead on the base substrate have an overlapping region with each other; and
a gate insulation layer located between the active layer and the gate metal layer, wherein the gate insulation layer comprises a first portion and a second portion, an orthographic projection of the first portion on the base substrate covers and exceeds the orthographic projection of the gate on the base substrate, and an orthographic projection of the second portion on the base substrate covers the orthographic projection of the first lead on the base substrate;
wherein a part, extending out of the gate, of the first portion has a first width value; at the overlapping region formed by the second lead and the first lead, a part, extending out of the first lead, of the second portion has a second width value; and the first width value is greater than the second width value.

2. The display substrate according to claim 1, wherein the second width value is less than or equal to 20% of the first width value.

3. The display substrate according to claim 1, wherein the second width value is 0.

4. The display substrate according to claim 3, wherein an extension direction of the second lead and an extension direction of the first lead are different; and
the orthographic projection of the first lead on the base substrate and the orthographic projection of the second portion on the base substrate overlap each other.

5. The display substrate according to claim 1, further comprising an interlayer insulation layer located between the gate metal layer and the source-drain metal layer; and
the source and the drain are electrically connected to the active layer through via holes running through the interlayer insulation layer.

6. A manufacturing method for a display substrate, wherein the display substrate is according to claim 1, and the manufacturing method comprises:
forming a pattern of an active layer on a base substrate;
forming an insulation film and a gate metal film successively on the pattern of the active layer;
forming a patterned photoresist layer on the gate metal film by using a semi-exposure photolithography process;
etching the gate metal film by using the patterned photoresist layer as a shield to form a pattern of a gate metal layer comprising a gate and a first lead;
dry etching the insulation film by using the patterned photoresist layer as a shield to form a pattern of a gate insulation layer comprising a first portion and a second portion, and removing the photoresist layer; and
forming a pattern of a source-drain metal layer comprising a source, a drain and a second lead on the pattern of the gate insulation layer.

7. The method according to claim 6, wherein the forming the patterned photoresist layer on the gate metal film by using the semi-exposure photolithography process comprises:
forming a positive photoresist film on the gate metal film; and
performing exposure and development treatment on the positive photoresist film by using a half-tone mask or a gray-tone mask, wherein in the pattern of the photoresist layer obtained, a part above a gate to be formed has a first thickness, and a part in an overlapping region formed by a first lead and a second lead to be formed has a second thickness, the first thickness being greater than the second thickness.

8. The method according to claim 7, wherein the half-tone mask or the gray-tone mask comprises a completely light-transmitting area and a partially light-transmitting area, the completely light-transmitting area corresponds to the first thickness in the photoresist layer, and the partially light-transmitting area corresponds to the second thickness in the photoresist layer.

9. The method according to claim 7, wherein the second thickness is less than or equal to half of the first thickness.

10. The method according to claim 6, wherein before the forming the pattern of the source-drain metal layer comprising the source, the drain and the second lead on the pattern of the gate insulation layer, the method further comprising:
forming an interlayer insulation layer with via holes on the pattern of the gate insulation layer, so that the source and the drain formed are electrically connected to the active layer through the via holes.

11. A display panel, comprising the display substrate of claim 1.

12. A display apparatus, comprising the display panel of claim 11.
